(19) United States
(12) Patent Application Publication
(10) Pub. No.: US 2010/0155853 A1
(43) Pub. Date: Jun. 24, 2010

(54) MULTIPLEXER AND METHOD OF MANUFACTURING THE SAME

(75) Inventor: Hong-Sik Yoon, Seongnam-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/641,836

(22) Filed: Dec. 18, 2009

(30) Foreign Application Priority Data
Dec. 19, 2008 (KR) 2008-129832

(51) Int. Cl. H01L 27/105; H03K 17/00; H01L 21/77

(52) U.S. Cl. 257/390; 340/2.2; 438/129; 257/E27.081; 257/E21.598

(57) ABSTRACT

A multiplexer can include a signal line arranged on a substrate and including a plurality of data wires extending in a first direction and electrically insulated from one another, where each of the data wires has at least one recess to provide at least two data wiring pieces. An address line is arranged on the signal line and includes a plurality of coding lines extending in a second direction different from the first direction and electrically insulated from the data wires. A plurality of switching elements are positioned in the recesses of the data wires and make electrical contact with the coding lines, where the switching element is configured to switch a data signal applied to the data wiring on and off in accordance with a coding signal applied to the coding lines, so that one of the data wires is selected according to a binary code of the address line corresponding to combinations of the coding lines to which coding signal is applied.

### CROSS-REFERENCE TO RELATED APPLICATION

This application claims priority under 35 U.S.C. §119 to Korean Patent Application No. 2008-129832, filed on Dec. 19, 2008 in the Korean Intellectual Property Office (KIPO), the contents of which are herein incorporated by reference in their entirety.

### FIELD

Example embodiments relate to a multiplexer and a method of manufacturing the same and a semiconductor device including the multiplexer, and more particularly, to a multiplexer manufactured by a half-line decoding process and a semiconductor device including the multiplexer.

### BACKGROUND

A memory cell region of a semiconductor device and a display unit of a flat panel display device generally include array structures arranged in a matrix shape and an allocation module, i.e., a multiplexer, usually divides the cell region or the display unit into a plurality of cells or blocks.

Particularly, in a recent semiconductor devices such as an integrated circuit device, a cell region of the semiconductor device generally includes a nano-structure of which the pattern width has a nanometer scale as the degree of integration of the semiconductor device is increased, while a peripheral region for electrically communicating with the cell region of the semiconductor device usually includes a micro-structure of which the pattern width has a micrometer scale or a sub-micrometer scale. For facilitating the electrical communication between the nano-structure in the cell region and the micro-structure in the peripheral region, a multiplexer/de-multiplexer circuit (hereinafter, MUX/DEMUX circuit or briefly multiplexer) has been widely used in the semiconductor device.

A recent increase of the integration degree of semiconductor devices reduces the pattern width and the pitch of the metal wiring in the cell region, and thus the MUX/DEMUX circuit has been upsized so as to improve electrical communication efficiency between the micro-structure in the peripheral region and the nano-scaled metal wiring in the cell region, which results in the size increase of the semiconductor device. For that reason, the driving mode of the MUX/DEMUX circuit has been changed into a half line decoding type from a direct decoding type so as to minimize an occupying space of the MUX/DEMUX circuit and the size of the semiconductor device.

According to the direct decoding type of the MUX/DEMUX circuit, a plurality of wiring lines crosses each other and a plurality of cross points of the wiring lines are allocated in a circuit matrix, and then each cell or block in the semiconductor device or the FPD device directly corresponds to each of the cross points of the wiring lines by one-to-one. The half line decoding type of the MUX/DEMUX circuit reduces a number of the wiring lines, for example, an address line, in spite of the decrease of decoding efficiency as compared with the direct decoding type, to thereby downsize of the MUX/DEMUX circuit.

According to the half line decoding type of the MUX/DEMUX circuit, n numbers of the address lines of the MUX/DEMUX circuit are usually designed to be electrically connected to ₙC_{n/2} numbers of signal lines of the MUX/DEMUX circuit. For example, 4 address lines of the MUX/DEMUX circuit are usually electrically connected to 6 signal lines of the MUX/DEMUX circuit.

Particularly, a single address line makes electrical contact with a number of signal lines at the same number of contact points and a binary code is allocated to each of the contact points between the address line and the signal lines by an electrical on/off. That is, the contact points of the address line and the signal lines function as a code unit of half line decoding type of the MUX/DEMUX circuit. Thus, the binary combination of the code units (binary code) of each address line of the MUX/DEMUX circuit usually is allocated to each cell or block in the semiconductor device or the FPD device. The code unit includes a short segment for generating a binary code ‘0’ and a conducting segment for generating a binary code ‘1.’ The short segment of the code unit comprises materials of relatively higher electrical resistance and thus the address line is electrically disconnected with the signal lines to be under a short circuit. In contrast, the conducting segment of the code unit comprises materials of relatively lower electrical resistance and thus the address line is electrically connected with the signal lines to be under an electrical circuit.

A pair of the short segments and a pair of the conducting segments are arranged on each of the signal lines of the conventional MUX/DEMUX circuit in such a configuration that the combination of the short and conducting segments on each of the address lines is different from each other. Thus, a binary code is allocated to each of the signal lines, and thus the signal lines of the conventional MUX/DEMUX circuit are differentiated from one another by the binary code.

According to a conventional process for forming the MUX/DEMUX circuit, a first thin layer comprising the material having relatively lower electrical resistance and a second thin layer comprising the material having relatively higher electrical resistance are sequentially formed on the signal lines and patterned into the short and conducting segments of each signal line by a patterning process. That is, the combination of the short and conducting segments are formed on each of the signal lines by the patterning process.

### SUMMARY

Example embodiments provide a multiplexer in which the short segment and the conducting segment are arranged into a single body to thereby reduce the manufacturing complexity of the short and conducting segments and improve operational reliability of the short and conducting segments.

Example embodiments also provide a method of manufacturing the above multiplexer. According to some example embodiments, a multiplexer can include a signal line arranged on a substrate and including a plurality of data wires extending in a first direction and electrically insulated from one another, where each of the data wires has at least one recess to provide at least two data wiring pieces. An address line is arranged on the signal line and includes a plurality of coding lines extending in a second direction different from the first direction and electrically insulated from the data wires. A plurality of switching elements are positioned in the recesses of the data wires and make electrical contact with the coding lines, where the switching element is configured to switch a data signal applied to the data wiring on and off in accordance with a coding signal applied to the coding lines, so that one of the data wires is selected according to a binary code of the address line corresponding to combinations of the coding lines to which coding signal is applied.

In an example embodiment, the multiplexer may further include an insulation pattern interposed between the data wires adjacent to each other to thereby electrically insulate the data wiring and an insulation interlayer on the insulation pattern and on the data wiring, so that the address line is arranged on the insulation interlayer in the second direction and electrically insulated from the data wires underlying the insulation interlayer.

In an example embodiment, the substrate may include a trench between the data wires adjacent to each other, the trench having a bottom lower than a surface of the substrate and being filled with the insulation pattern.

In an example embodiment, a pair of the recesses are positioned at each of the data wires extending in the first direction such that a pattern of the recesses at each of data wires is different from each other in the first direction and at least two recesses positioned in different data wires are arranged in a line along the second direction, so that the switching elements in the recesses are arranged in a line along the coding wirings extending in the second direction.

In an example embodiment, the multiplexer may further include a gate insulation layer covering a surface of the substrate exposed through the recess and sidewalls of the data wiring pieces that define the recess, so that the switching element includes a field effect transistor (FET) having a gate structure that is positioned on the gate insulation layer in the recess. For example, the gate insulation layer and the insulation interlayer may include one of silicon oxide and metal oxide having high dielectric constant.

In an example embodiment, wherein the signal line and the address line includes any one material selected from the group consisting of polysilicon doped with impurities, a metal and a conductive polymer.

According to some example embodiments, there is provided a method of manufacturing the above multiplexer. A signal line may be formed on a substrate. The signal line may include a plurality of data wires extending in a first direction and electrically insulated from one another and each of the data wiring may have at least one recess such that the data wiring is separated into at least two data wiring pieces. A plurality of switching elements may be formed in the recesses of the data wires. The switching element may be arranged in a second direction different from the first direction and may be selectively switched on or off a data signal applied to the data wiring in accordance with a coding signal. An address line may be formed on the signal line. The address line may include a plurality of coding lines extending in the second direction and electrically insulated from the data wires such that the coding lines make electrical contact with the switching elements, so that one of the data wires is selected according to a binary code of the address line corresponding to combinations of the coding wirings to which the coding signal is applied.

In an example embodiment, the signal line including the data wires may be exemplarily fowled through the following steps: a first conductive layer may be formed on the substrate and a hard mask pattern may be formed on the first conductive layer. Thus, the first conductive layer may be partially exposed through the hard mask pattern. Then, the first conductive layer may be partially removed from the substrate by an etching process using the hard mask pattern as an etching mask, to thereby form a first conductive pattern on the substrate. The hard mask pattern may be removed from the first conductive pattern and finally the data wires may be formed on the substrate.

In an example embodiment, the switching elements may be exemplarily formed through the following process steps: A pair of the recesses may be formed at each of the data wires extending in the first direction such that a pattern of the recesses at each of data wires is different from each other in the first direction and at least two recesses positioned in different data wires are arranged in a line along the second direction, so that the switching elements in the recesses are arranged in a line along the coding wirings extending in the second direction. An insulation layer may be formed on the data wires, on the insulation pattern, on a surface of the substrate exposed through the recess and on sidewalls of the data wiring pieces that define the recess. Then, semiconductor structures may be foamed on the insulation layer in the recesses of the data wires of the signal line.

According to some example embodiments of the present inventive step, the conventional short segment and the conducting segment having different electrical resistance are formed into a single switching element through a single manufacturing process, to thereby improve manufacturing efficiency and operational reliability of the multiplexer.

### BRIEF DESCRIPTION OF THE DRAWINGS

Example embodiments will be more clearly understood from the following detailed description taken in conjunction with the accompanying drawings.

FIG. 1 is a perspective view illustrating a multiplexer in accordance with an example embodiment of the inventive concept;

FIG. 2A is a cross-sectional view cut along a line I-I′ of the multiplexer shown in FIG. 1;

FIG. 2B is a partially enlarged view illustrating a portion R of the multiplexer shown in FIG. 2A;

FIG. 3 is a view illustrating the arrangement of the recesses at the data wires of the multiplexer shown in FIG. 1;

FIG. 4 is a view illustrating cross points of the signal line and the address line of the multiplexer having the arrangement of the recesses at the data wires shown in FIG. 3;

FIG. 5 is a view illustrating an example flow of the data signal in the multiplexer shown in FIG. 4;

FIG. 6 is a perspective view illustrating a modified multiplexer for decreasing signal disturbance in accordance with an example embodiment of the present invention;

FIG. 7 is a view illustrating a semiconductor device including the multiplexer shown in FIG. 1 in accordance with an example embodiment of the present example embodiment; and

FIGS. 8A to 8G are cross-sectional views illustrating a method of manufacturing the multiplexer shown in FIG. 1 in accordance with an example embodiment of the present inventive concept.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

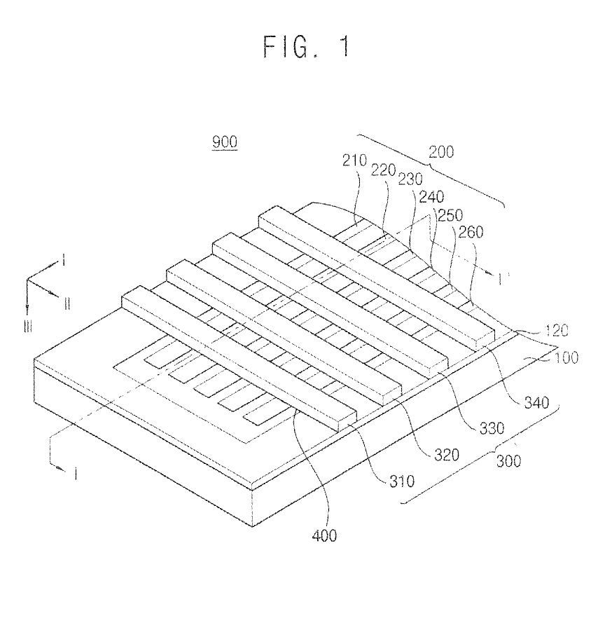

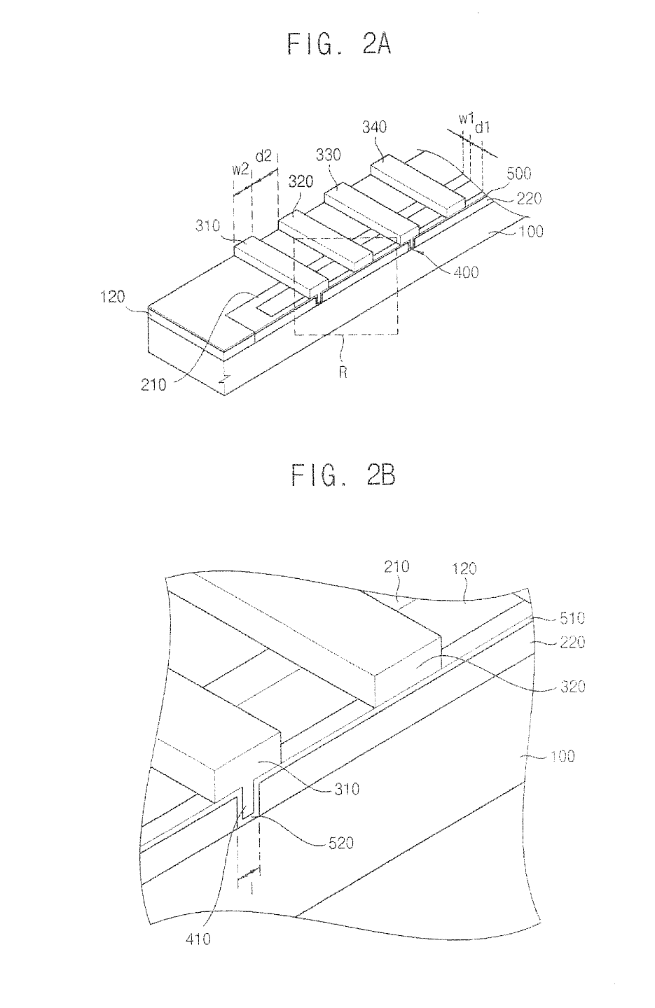

FIG. 1 is a perspective view illustrating a multiplexer in accordance with an example embodiment of the inventive concept. FIG. 2A is a cross-sectional view cut along a line I-I′ of the multiplexer shown in FIG. 1 and FIG. 2B is a partially enlarged view illustrating a portion R of the multiplexer shown in FIG. 2A.

Referring to FIG. 1, a multiplexer 900 in accordance with an example embodiment of the present inventive concept may include a plurality of signal lines 200 extending on a substrate 100 in a first direction I and electrically insulated from each other, a plurality of address lines 300 extending over the signal lines 200 in a second direction II different from the first direction I and electrically insulated from the signal lines 200 and a plurality of switching elements 400 (a single one is highlighted in FIG. 1 as an example) arranged at cross sections of the signal line and the address line. Transmission of a data signal through the signal lines 200 may be controlled by the switching elements 400 in accordance with a coding signal transmitting through the address line 300. Therefore, the multiplexer 900 may discriminate and identify the plurality of the signal lines 200 by combinations of the coding signals transmitting through the address line 300.

In an example embodiment, the substrate 100 may comprise a semiconductor material and thus may include a channel through which electrons or holes may pass under a surface thereof on which the switching element 400 may be formed. That is, the electrons or the holes may pass through the channel under the switching element 400 in accordance with the operation of the switching element 400. Examples of the substrate 100 comprising the semiconductor material may include a polysilicon substrate such as a wafer, a germanium (Ge) substrate and a silicon-germanium (Si—Ge) substrate. Thus, the data signal may be transmitted through the signal lines 200 or may be short-circuited by the switching element 400.

In an example embodiment, the signal lines 200 may extend on the substrate 100 in the first direction I and may have a first width w1 in the second direction II. For example, a plurality of data wires 210 to 260 may be arranged in the first direction I and be spaced apart from each other by a first gap distance d1 in the second direction II. In the present example embodiment, the signal lines 200 may include a conductive pattern extending in the first direction I on the substrate 100. The conductive pattern may comprise materials having relatively lower electrical resistance thus the electrical signal may be efficiently transmitted through the data wires 210 to 260. Examples of the material having the lower electrical resistance may include polysilicon doped with a lower electrically resistive material, a conductive polymer and a lower electrical resistive metal such as copper (Cu), aluminum (Al), platinum (Pt) and tungsten (W).

In an example embodiment, an insulation pattern 120 may be positioned on the substrate 100 in such a configuration that the gap space between the data wires 210 to 260 may be filled up with the insulation pattern 120 and the data wires 210 to 260 may be exposed through the insulation pattern 120. Accordingly, the data wires 210 to 260 may be electrically insulated from each other by the insulation pattern 120.

For example, the insulation pattern 120 may comprise a material having good gap-fill characteristics such as BPSG (boron phosphorus silicate glass), PSG (phosphorus silicate glass), FSG (fluorinated silicate glass), PETEOS (plasma enhanced tetra ethyl ortho-silicate), USG (undoped silicate glass) and an oxide deposited by a high density plasma chemical vapor deposition (HDPCVD) process.

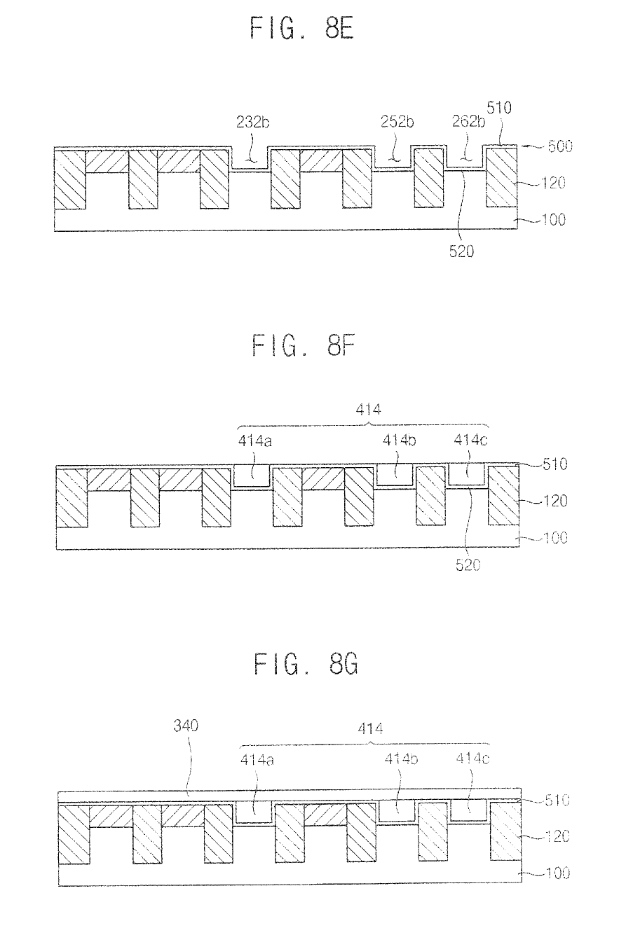

For example, the substrate 100 may further include a trench 110 shown in FIG. 8B between the data wires 210 to 260 and thus the insulation pattern 120 may have a thickness corresponding to a depth of the trench 110 and a height of the signal lines 200 and have a width corresponding to the first gap distance d1.

The number of the signal lines 200 may be varied in accordance with characteristics and requirements of the semiconductor device including the multiplexer 900. In the present example embodiment, six signal lines 200 and four address lines 300 may be arranged on the substrate 100 and one of the signal lines 200 may be selected by the combinations of the coding signals transmitting through the address lines 300 under the half line coding process.

In an example embodiment, each of the data wires 210 to 260 may be partially removed from the substrate 100 and thus may include a pair of recesses 212 to 262 through which a surface of the substrate 100 may be exposed. Therefore, each data wiring may be divided into three wiring pieces by the recesses 212 to 262 and the wiring pieces may be electrically insulated from one another. The data signal passing through the data signals 210 to 260 may be short-circuited by the recesses 212 to 262 and thus may not be transmitted through the data wires 210 to 260.

For example, each pair of the recesses 212 to 262 at the data wiring 210 to 260 may be arranged into first patterns different from one another along the first direction I to thereby form longitudinal combinations different from one another in the first direction. Some of the recesses 212 to 262 at different data wires 210 to 260 may be arranged into second patterns in a line along the second direction II to thereby form latitudinal combinations different from one another in the second direction II. In the present example embodiment, a pair of the recesses may be arranged on each of the data wires 210 to 260 in such a configuration that each pair of the recesses may have different positions and intervals on the data wires 210 to 260 along the first direction, and thus six longitudinal combinations may be prepared. In addition, three recesses at different data wires may be arranged in a line along the second direction II, and thus four latitudinal combinations may be prepared.

In an example embodiment, an insulation layer 500 may be arranged on the substrate 100 including the data wires 210 to 260 and recesses 212 to 262. For example, the insulation layer 500 may include an insulation interlayer 510 and a gate insulation layer 520. The insulation interlayer 510 may be coated on the data wires 210 to 260 and on the insulation pattern 120 between the data wires 210 to 260. The gate insulation layer 520 may be coated sidewalls of the data wires 210 to 260 that may define the recesses 212 to 262 and a bottom of the recesses 212 to 262 corresponding to the surface of the substrate 100 exposing through the recesses 212 to 262.

The address line 300 may be arranged on the insulation interlayer 510 and thus the signal lines 200 and the address line 300 may be electrically insulated from each other by the insulation interlayer 510. The insulation interlayer 510 may comprise an oxide or a nitride having good deposition and insulation characteristics. In the present example embodiment, the insulation interlayer 510 may have a sufficient thickness enough to electrically insulate the signal lines 200 and the address line 300.

The gate insulation layer 520 may be coated on the bottom and sidewalls of the recesses 212 to 262 by which the data wires 210 to 260 may be separated into wiring pieces, and thus a semiconductor structure 410 in the recess may be electrically insulated from the substrate 100. Thus, the semiconductor structure in the recess may function like a gate electrode in a transistor. That is, a channel region may be formed at a surface portion of the substrate 100 in each of the recesses 212 to 262 and the channel region may be electrically insulated from the semiconductor structure in each of the recesses 212 to 262. Thus, electrons or electric holes may flow through the channel region under the bottom of the recesses 212 to 262 in accordance with a gate voltage applied to the semiconductor structure in the recesses 212 to 262 and thus the separated data wiring pieces may be electrically connected to each other or may be short-circuited by the recesses 212 to 262. Accordingly, a switching element 400 may be positioned in each of the recesses 212 to 262 and the data signal may pass or short-circuited through the signal lines 200 by the switching element.

In the present example embodiment, the gate insulation layer 520 may have a thickness of about 20 Å to about 40 Å and may comprise an oxide having a high dielectric constant such as silicon oxide (SiOx) and aluminum oxide (Al2O3).

The above example embodiment of the present inventive concept may disclose the insulation interlayer 510 and the gate insulation layer 520 may have different compositions, the insulation interlayer 510 and the gate insulation layer 520 may comprise the same materials, as would be known to one of the ordinary skill in the art.

The semiconductor structure 410 may be positioned on the gate insulation layer 520 in each of the recesses 212 to 262 as the switching element 400.

For example, the semiconductor structure 410 may include a gate structure on the gate insulation layer 520 in the recesses 212 to 262 and may comprise semiconductor materials such as silicon (Si), germanium (Ge), gallium arsenide (GaAs) and polysilicon doped with impurities. The semiconductor structure 410 may be electrically connected to the address line 300 and thus a coding signal may be transmitted to the semiconductor structure 410 through the address line 300.

When the coding signal is applied to the semiconductor structure 410, the channel region may be formed at the surface portion of the bottom of the recess and the data wiring pieces may be electrically connected to each other in the first direction I to thereby form the signal lines 200 through which the data signal may be transmitted. When the coding signal is not applied to the semiconductor structure 410, the channel region may disappear at the surface portion of the bottom of the recess and thus the signal lines 200 may be again separated into the data wiring pieces by the recesses 212 to 262. Therefore, the gate insulation layer 520, the semiconductor structure 410 in the recess and a pair of the data wiring pieces symmetrical with respect to the semiconductor structure 410 and defining the recess may function as a field effect transistor (FET) providing a switching element 400 for selectively switching on or off the data signal passing through the signal lines 200. Accordingly, a plurality of the switching elements 400 may be positioned in the recesses 212 to 262, respectively, and the data signal may be selectively transmitted through the signal lines 200 by the switching elements 400.

In an example embodiment, the address line 300 may extend on the insulation interlayer 510 in the second direction II different from the first direction I and may have a second width w2 in the first direction I. For example, a plurality of addressing wirings 310 to 340 may be arranged in the second direction II and be spaced apart from each other by a second gap distance d2 in the first direction I. In the present example embodiment, the address line 300 may include a conductive pattern extending in the second direction II on the insulation interlayer 510.

Likewise the signal lines 200, the conductive pattern of the address line 300 may comprise materials having relatively lower electrical resistance thus the coding signal applied to each of the coding wirings 310 to 340 may be efficiently transmitted to the semiconductor structure 410 in the recess. Examples of the material having the lower electrical resistance may include polysilicon doped with a lower electrically resistive material, a conductive polymer and a lower electrical resistive metal such as copper (Cu), aluminum (Al), platinum (Pt) and tungsten (W).

In an example embodiment, the address line 300 may be arranged in the second direction II in such a configuration that the coding wirings 310 to 340 may be simultaneously make electrical contact with the semiconductor structures 410 in the recesses 212 to 262 in the second direction II. Therefore, in the present example embodiment, the coding signal applied to one of the coding wirings 310 to 340 may be simultaneously transmitted to three different semiconductor structures 410 and thus three data wires may be simultaneously switched on or off by a single coding signal. Accordingly, each of the data wires 210 to 260 may be differentiated from one another by the combinations of the coding signals applied to each of the coding wirings 310 to 340, and thus data signals may be transmitted through one of the data wires by selection of the combinations of the coding signals.

According to the present example embodiment of the multiplexer, each of the data wires of the signal line may include a pair of transistors as a switching element and single wirings among the data wires may be selected by the combinations of the coding signals that are applied to the coding wirings of the address line. That is, the data signal may be transmitted through the selected data wiring by the control of the combinations of the coding signals, to thereby improve operation stability and manufacturing efficiency of the multiplexer. Particularly, the manufacturing process for the multiplexer may be similar to the process for manufacturing a semiconductor device and thus the operation stability of the multiplexer may be remarkably increased as compared with conventional multiplexers.

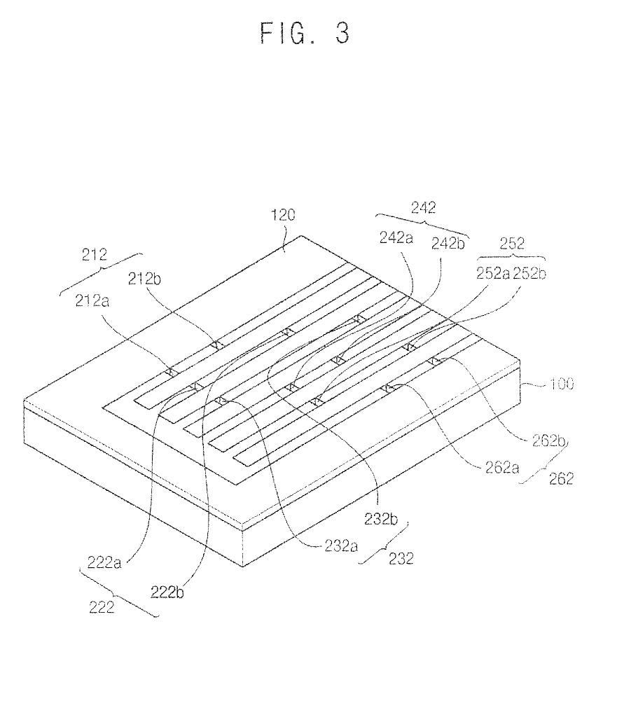

Hereinafter, routing operation by the multiplexer 900 shown in FIG. 1 will be described in detail with reference to FIGS. 3 to 5.

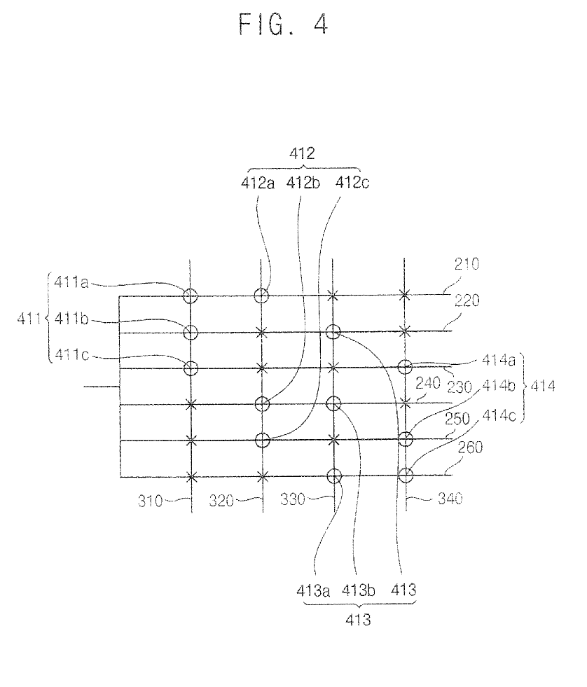

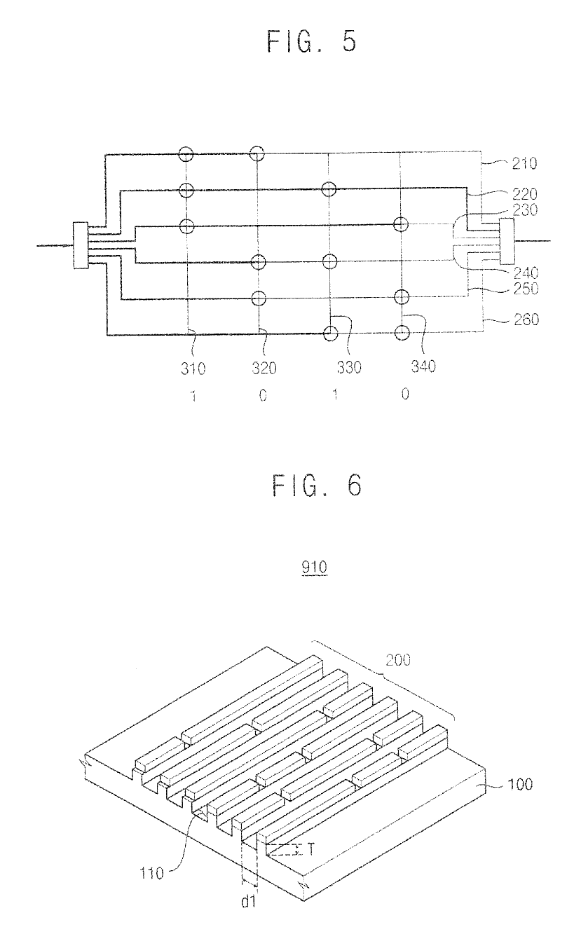

FIG. 3 is a view illustrating the arrangement of the recesses at the data wires of the multiplexer shown in FIG. 1 and FIG. 4 is a view illustrating cross points of the signal line and the address line of the multiplexer having the arrangement of the recesses at the data wires shown in FIG. 3. FIG. 5 is a view illustrating an example flow of the data signal in the multiplexer shown in FIG. 4. In FIG. 5, a second data wiring 220 may be selected as a conductive wiring by the combinations of the coding signals as an example embodiment of the present invention. In addition, a plurality of the semiconductor structures 410 may be grouped into first-lined to fourth-lined semiconductor structures in accordance with the coding wirings 310 to 340 that make electrical contact with the semiconductor structures 410 and extend in a line along the second direction II. That is, the first-lined semiconductor structures indicate the semiconductor structures making electrical contact with the first coding wirings in a line extending the second direction II and the second semiconductor structures indicate the semiconductor structures making electrical contact with the second coding wirings in a line extending the second direction II. The first-lined to fourth-lined semiconductor structures may be denominated as reference numeral 411, 412,413 and 414, respectively, and the reference numeral 410 may indicate a general semiconductor structures including all of the first-lined to fourth-lined semiconductor structures.

Referring to FIG. 3, first and second recesses 212a and 212b may be arranged at a first data wiring 210 and third and fourth recesses 222a and 222b may be arranged at a second data wiring 220. In the same way, fifth and sixth recesses 232a and 232b, seventh and eighth recesses 242a and 242b, ninth and tenth recesses 252a and 252b and eleventh and twelfth recesses 262a and 262b may be arranged at a third data wiring 230, a fourth data wiring 240, a fifth data wiring 250 and a sixth data wiring 260, respectively.

Then, as shown in FIG. 4, a first coding wiring 310 of the address line 300 may make electrical and contact with first, second and third semiconductor structures 411a, 411b and 411c of the first-lined semiconductor structures 411 that may be positioned in the first, third and fifth recesses 212a, 222a and 232a, respectively, in the second direction II. Thus, the transmission of the data signals through the first, second and third data wires 210, 220 and 230 may be controlled or switched on/off by the coding signal applied to the first coding wiring 310 of the address line 300. That is, the first, second and third semiconductor structures 411a, 411b and 411c may function as first switching elements 400, respectively, by the coding signal applied to the first coding wiring 310, and thus the data signals applied to the first, second and third data wires 210, 220 and 230 may be transmitted to the next data wiring piece of the data wires 210, 220 and 230 or may be cut off at the first, third and fifth recesses 212a, 222a and 232a, respectively. A second coding wiring 320 of the address line 300 may make electrical contact with fourth, fifth and sixth semiconductor structures 412a, 412b and 412c of the second-lined semiconductor structures 412 that may be positioned in the second, seventh and ninth recesses 212b, 242a and 252a, respectively, in the second direction II. Thus, the transmission of the data signals through the first, fourth and fifth data wires 210, 240 and 250 may be controlled or switched on/off by the coding signal applied to the second coding wiring 320 of the address line 300. That is, the fourth, fifth and sixth semiconductor structures 412a, 412b and 412c may function as a second switching element of the first data wiring 210 and first switching element of the fourth and fifth data wires 240 and 250, respectively, by the coding signal applied to the second coding wiring 320, and thus the data signals applied to the first, fourth and fifth data wires 210, 240 and 250 may be transmitted to the next data wiring piece of the data wires 210, 240 and 250 or may be cut off at the second, seventh and ninth recesses 212b, 242a and 252a, respectively. A third coding wiring 330 of the address line 300 may make electrical and contact with seventh, eighth and ninth semiconductor structures 413a, 413b and 413c of the third-lined semiconductor structures 413 that may be positioned in the fourth, eighth and eleventh recesses 222b, 242b and 262a, respectively, in the second direction II. Thus, the transmission of the data signals through the second, fourth and sixth data wires 220, 240 and 260 may be controlled or switched on/off by the coding signal applied to the third coding wiring 330 of the address line 300. That is, the seventh, eighth and ninth semiconductor structures 413a, 413b and 413c may function as a second switching element of the second and fourth data wires 220 and 240 and first switching element of the sixth data wiring 260, respectively, by the coding signal applied to the third coding wiring 330, and thus the data signals applied to the second, fourth and sixth data wires 220, 240 and 260 may be transmitted to the next data wiring piece of the data wires 220, 240 and 260 or may be cut off at the fourth, eighth and eleventh recesses 222b, 242b and 262a, respectively. A fourth coding wiring 340 of the address line 300 may make electrical and contact with tenth, eleventh and twelfth semiconductor structures 414a, 414b and 414c of the fourth-lined semiconductor structures 414 that may be positioned in the sixth, tenth and twelfth recesses 232b, 252b and 262b, respectively, in the second direction II. Thus, the transmission of the data signals through the third, fifth and sixth data wires 230, 250 and 260 may be controlled or switched on/off by the coding signal applied to the fourth coding wiring 340 of the address line 300. That is, the tenth, eleventh and twelfth semiconductor structures 414a, 414b and 414c may function as second switching elements of the third, fifth and sixth data wires 230, 250 and 260, respectively, by the coding signal applied to the fourth coding wiring 330, and thus the data signals applied to the third, fifth and sixth data wires 230, 250 and 260 may be transmitted to the next data wiring piece of the data wires 230, 250 and 260 or may be cut off at the sixth, tenth and twelfth recesses 232b, 252b and 262b, respectively.

For example, when the coding signals may be applied to the first and third coding wirings 310 and 330, respectively, and no coding signal may be applied to the second and fourth coding wirings 320 and 340 on condition that the data signals may be applied to the signal lines 200 through a contact pad (not shown), the first, second and third semiconductor structures 411a, 411b and 411c may function as an on-switch in the first, third and fifth recesses 212a, 222a and 232a of the first, second and third data wires 210, 220 and 230. That is, the first, third and fifth recesses 212a, 222a and 232a may be coded as an electrical on-state and thus the data signals may be transmitted through all of the data wires 210 to 260. Therefore, the data signals may reach next cross points of the signal lines 200 and the second coding wiring 320 through all of the data wires 210 to 260.

No coding signal may be applied to the second coding wiring 320 and thus the fourth, fifth and sixth semiconductor structures 412a, 412b and 412c may function as an off-switch in the second, seventh and ninth recesses 212b, 242a and 252a of the first, fourth and fifth data wires 210, 240 and 250. Therefore, the data signals may be transmitted merely through the second, third and sixth data wires 220, 230 and 260 by combination of the first and second coding wirings 310 and 320 and may reach next cross points of the signal lines 200 and the third coding line 330.

Since the coding signal may be applied to the third coding wiring 330, the seventh, eighth and ninth semiconductor structures 413a, 413b and 413c may function as an on-switch in the fourth, eighth and eleventh recesses 222b, 242b and 262a of the second, fourth and sixth data wires 220, 240 and 260. That is, the fourth, eighth and eleventh recesses 222b, 242b and 262a may be coded as an electrical on-state and thus the data signals may be transmitted merely through the second, fourth and sixth data wires 220, 240 and 260. However, the data signal transmitting through the fourth data wiring 240 has been already cut off at the seventh recess 242a and thus no further data signal may be transmitted at the eighth recess 242b although the eighth recess 242b may be coded as an electrical on-state. That is, the data signal may not be transmitted through the fourth data wiring 240 over the seventh recess 242a. Therefore, the data signals may transmitted merely through the second and sixth data wires 220 and 260 by combination of the first, second and third coding wirings 210, 320 and 330. The data signals transmitting the fourth and eleventh recesses 222b and 262a may reach next cross points of the signal lines 200 and the fourth coding wiring 340.

However, no coding signal may be applied to the fourth coding wiring 340 and thus the tenth, eleventh and twelfth semiconductor structures 414a, 414b and 414c may function as an off-switch in the sixth, tenth and twelfth recesses 232b, 252b and 262b of the third, fifth and sixth data wires 230, 250 and 260. Therefore, the data signals may be transmitted merely through the first, second and fourth data wires 210, 220 and 240. However, the data signal transmitting through the first and fourth data wires 210 and 240 has been already cut off at the second and seventh recesses 212b and 242a and thus no further data signal may be transmitted through the first and fourth data wings 210 and 240. Therefore, the data signals may be transmitted just merely through the second data wiring 220 by combination of the first, second, third and fourth coding wirings 310, 320, 330 and 340. Accordingly, when the exemplarily code may be applied to the address line 300, the second data wiring 210 of the signal lines 200 may be selected as an active line as shown in FIG. 5. In the above code of the address line 300, the binary digit ‘0’ indicates that no coding signal is applied to a corresponding coding wiring of the address line 300 and the binary digit ‘1’ indicates that coding signal is applied to a corresponding coding wiring of the address line 300. Therefore, the above code indicates that the coding signals are applied to the first and third coding wirings of the address line 300 and are not applied to the second and fourth coding wirings of the address line 300, as shown in FIGS. 4 and 5.

Therefore, the multiplexer 900 may select one of the data wires of the signal lines 200 by the binary code of the address line 300 through the above-described routing process.

Since the binary code of the address line 300 may be caused by a channel mechanism of a transistor at each of the recesses of the data wires 210 to 260, the signal disturbance Ds between the neighboring data wires may be determined by a ratio of a length 1 of the recess along the first direction I with respect to a surface length S between the neighboring data wires along the second direction II, as expressed in the following equation (1).

$${D}_{s} = k \frac{l}{S} \\ ( k \text{:} proportional constant ) \qquad ( 1 )$$

That is, the signal disturbance Ds may be proportional to the length 1 of the recess and reversely proportional to the surface length S between the neighboring data wires. In the present example embodiment, the surface length S between the neighboring data wires may be substantially identical to the first gap distance d1 along the second direction II in the multiplexer 900, as illustrated in FIG. 1. Thus, the signal disturbance Ds may be expressed as the following equation (2).

$${D}_{s} = k \frac{l}{{d}_{1}} \\ ( k \text{:} proportional constant ) \qquad ( 2 )$$

The size of the multiplexer 900 may be reduced according to recent semiconductor device trends of fine pattern and small size. In case that the size of the multiplexer 900 may be reduced without any reduction of the size of the recess at each of the data wires, the substrate 100 may be easily modified in such a manner that the surface length between the neighboring data wires may be increased sufficiently to prevent the signal disturbance Ds.

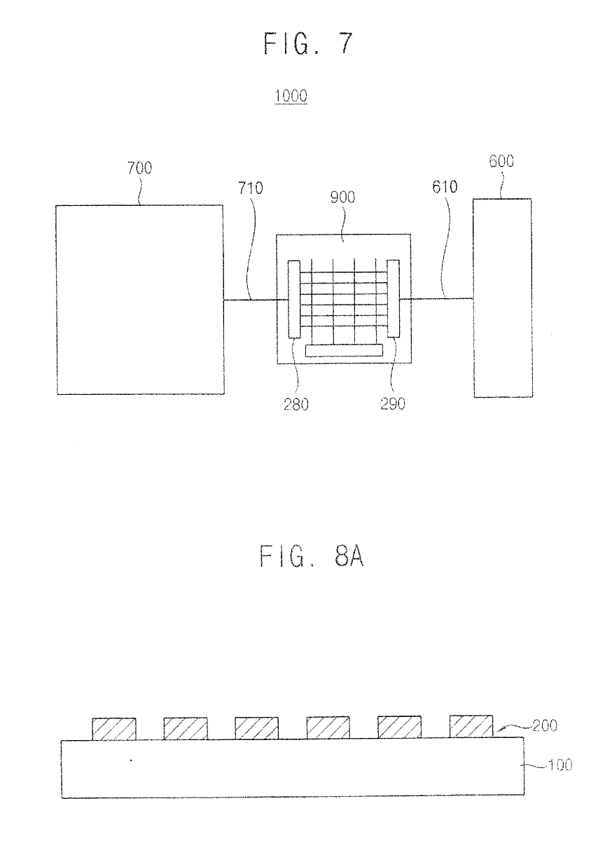

FIG. 6 is a perspective view illustrating a modified multiplexer for decreasing signal disturbance in accordance with an example embodiment of the present invention. In FIG. 6, the signal disturbance of the multiplexer 910 is largely improved due to the modification of the substrate 100 in view of the signal lines 200 at which the recesses are formed and thus the address line 300 of the modified multiplexer 910 is omitted.

Referring to FIG. 6, the modified multiplexer 910 may further include a plurality of trenches 110 at the substrate 100 between the neighboring data wires 210 to 260. The trench 110 may increase the surface length S between the neighboring data wires to thereby decrease the signal disturbance Ds.

Particularly, the surface length S between neighboring data wires may be increased as long as a side length T corresponding to the depth of the trench 110 as expressed in equation (3).

S=2T+d₁ (3)

Therefore, the signal disturbance Ds between the neighboring data wires may be expressed the following equation (4) in the modified multiplexer 910.

$${D}_{s} = k \frac{l}{2 T + {d}_{1}} \qquad ( 4 )$$

That is, the signal disturbance Ds of the multiplexer 910 may be decreased in proportional to the side length T of the trench 110. Therefore, although the first gap distance d1 between the data wires of the multiplexer may be decreased as the high integration degree of the semiconductor device including the multiplexer, the trench 110 of the substrate 100 between the data wires may be sufficiently reduce the signal disturbance Ds between the data wires.

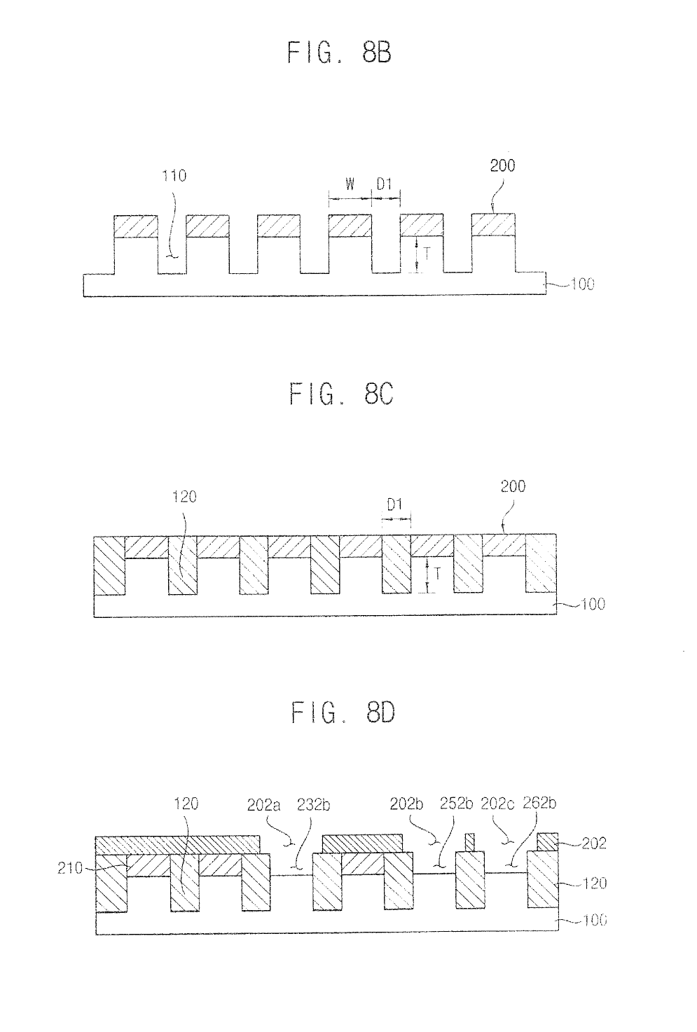

FIG. 7 is a view illustrating a semiconductor device including the multiplexer shown in FIG. 1 in accordance with an example embodiment of the present example embodiment. The multiplexer of the semiconductor device 1000 in FIG. 7 substantially has the same structure as the multiplexer described in detail with reference to FIG. 1, and thus the same reference numerals in FIG. 7 denote the same elements In FIG. 1 and the detailed descriptions of the same elements will be omitted.

Referring to FIG. 7, a semiconductor device 100 in accordance with an example embodiment of the present inventive concept may include a data process unit 700 for processing various data and a peripheral unit 600 for electrically communicating with the data process unit 700 and from which data signal may be transferred into the data process unit 700 and to which processed data may be transferred from the data process unit 700. The multiplexer 900 may be positioned between the data process unit 700 and the peripheral unit 600 and may select one of the data wires in the signal lines 200 in accordance with a cell or a block of the data process unit 700.

In an example embodiment, a first end of the signal lines 200 may be electrically connected to a first contact pad 280 and the first contact pad 280 may be electrically connected to the semiconductor device 1000 through a first connection line 710. A second end opposite to the first end the of the signal lines 200 may be connected to the second contact pad 290 and the second contact pad 290 may be electrically connected to the peripheral unit 600 through a second connection line 610.

For example, the data process unit 700 may include a cell region of a volatile or a non-volatile memory device such as a dynamic random access memory (DRAM) device and a flash memory device. Thus, the first connection line 710 may be electrically connected to a metal wiring of the memory device. The peripheral unit 600 may include logic cells for driving and controlling cells of the memory devices.

Therefore, selection of one of the data wires in the multiplexer 900 may cause a data signal to transfer merely into a predetermined cell or block of the memory device and the processed data signal in a cell or a block of the memory device may be transferred into the peripheral unit 600 merely through a corresponding data wiring in the multiplexer 900.

While the above example embodiment of the present inventive concept discloses the multiplexer in a semiconductor device such as a memory device, the multiplexer may also be installed to any kind of electric devices only if that the device needs a transfer unit for transferring data signals and a process unit for processing the data signals. For example, the electric device may include flat panel display (FPD) device in which an image may be displayed on flat panel due to the control of a plurality of pixels in the flat panel by data signals and scanning signals. In such a case, the multiplexer may be positioned between a display unit and a data signal driving unit and thus the data signals may be transferred merely into a predetermined cell or block of the display unit.

Hereinafter, a method of manufacturing the multiplexer will be described in detail with reference to FIGS. 8A to 8G.

FIGS. 8A to 8G are cross-sectional view illustrating processing steps for a method of manufacturing the multiplexer shown in FIG. 1 in accordance with an example embodiment of the present inventive concept.

Referring to FIGS. 1 and 8A, the signal lines 200 may be formed on the substrate 100.

In an example embodiment, a first conductive layer (not shown) may be formed on the substrate 100 comprising semiconductor materials. Examples of the semiconductor material may include silicon (Si), germanium (Ge), silicon germanium (SiGe) and combinations thereof. The first conductive layer may comprise materials having lower electrical resistance such as conductive polymer, copper (Cu), aluminum (Al), platinum (Pt), tungsten (W), poly-silicon doped with impurities and combinations thereof. The first conductive layer may be formed into the signal lines 200 in a consecutive process.

Various deposition processes may be used for formation of the first conductive layer. When the first conductive layer may comprise polysilicon or conductive polymer, a low pressure chemical vapor deposition (LPCVD) process or an atmospheric pressure CVD (APCVD) process may be used for formation of the first conductive layer. In contrast, when the first conductive layer may comprise a conductive metal, a physical vapor deposition (PVD) process, a plasma-enhanced CVD (PECVD) process, an atomic layer deposition (ALD) process or a sputtering process may be used for formation of the first conductive layer.

A pad oxide layer (not shown) may be faulted on the first conductive layer and a silicon nitride may be formed on the pad oxide layer to thereby form a hard mask layer (not shown) on the pad oxide layer. Thus, the hard mask layer may be prevented from making direct contact with the first conductive layer by the pad oxide layer. Composition materials of the pad oxide layer may be varied in accordance with composition materials of the first conductive layer.

A first photoresist pattern (not shown) corresponding to the signal lines 200 may be formed on the hard mask layer by a photolithography process and the hard mask layer, the pad oxide layer and the first conductive layer may be sequentially removed from the substrate 100 by an etching process using the first photoresist pattern as an etching mask, to thereby form a first conductive pattern (not shown), a pad oxide pattern (not shown) and a first hard mask pattern (not shown) that are sequentially stacked on the substrate 100. Thereafter, the pad oxide pattern and the first hard mask pattern may be removed from the first conductive pattern to thereby form the signal lines 200 having the data wires 210 to 260 extending along the first direction on the substrate 100.

In an example embodiment, each of the data wires 210 to 260 may have the first width w1 and may be spaced apart from one another by the first gap distance d1. Particularly, when the trench 100 may be formed on the substrate between the neighboring data wires, the pad oxide pattern and the first hard mask pattern may be removed from the first conductive pattern after formation of the trench 110.

While the above example embodiment discloses that the signal lines 200 may be formed on the substrate 100 by the etching process using the first hard mask pattern as an etching mask, any other processes known to ordinary skill in the art may also be used in place of or in conjunction with the etching process in accordance with the composition materials of the first conductive layer. For example, the first conductive layer may be formed into the first conductive pattern by an imprinting process using a mold pattern corresponding to the signal lines 200. Particularly, a nano-imprinting process or a nano-lithography process may be utilized for the formation of the first conductive pattern when the first gap distance d1 between the data wires of the signal lines 200 may be significantly reduced.

Referring to FIG. 8B, the trench 110 may be formed on the substrate 100 between the neighboring data wires, and thus the surface length S of the data wires may be sufficiently increased in the multiplexer 900.

In an example embodiment, the substrate 100 may be partially etched off between the data wires using the first hard mask pattern as an etching mask, to thereby form the trenches 110 on the substrate 100 between the neighboring data wires 210 to 260. The etching process against the substrate 100 may include a dry etching process or a plasma etching process.

For example, the trench 110 may be formed to have a depth from a top surface of the substrate 100 so that the trench 110 may have a sidewall of a side length T. Thus, the surface length S between the neighboring data wires may be calculated according to Equation (3) and the signal disturbance Ds may be calculated according to Equation (4). Therefore, the depth or the side length T may be determined in such a way that the signal disturbance Ds may be sufficiently reduced according to Equation (4).

The trench 110 may be prepared on the substrate 100 so as to increase the surface length S and to increase the signal disturbance Ds. Thus, in case that the first gap distance d1 between the neighboring data wires in the signal lines 200 may be sufficiently large and thus the signal disturbance Ds may be ignorable, the trench need not be prepared on the substrate 100, as would be known to one of the ordinary skill in the art.

Referring to FIG. 8C, an insulation pattern 120 may be formed on the substrate 100 in such a manner that a first space in the trenches 110 and a second space between the data wires 210 to 260 of the signal lines 200 may be sufficiently filled up with the insulation pattern 120.

In an example embodiment, an oxide or a nitride may be deposited onto the substrate 100 including the trenches 110 and the data wires 210 to 260 to a sufficient thickness to fill up the first and second spaces, to thereby form a lower insulation layer (not shown) on the substrate 100. The data wires 210 to 260 may be electrically insulated from one another and thus each of the data wires 210 to 260 may function as a conductive wiring independently from one another.

For example, the lower insulation layer may be formed on the substrate 100 by one of a CVD process, a PECVD process and a high-density plasma CVD (HDPCVD) process and may comprise boron phosphorus silicate glass (BPSG), phosphorus silicate glass (PSG), fluorinated silicate glass (FSG), plasma enhanced tetra ethyl orthosilicate (PETEOS), undoped silicate glass (USG) and combinations thereof. In the present example embodiment, the lower insulation layer may comprise an oxide deposited by the HDPCVD process or USG and thus may have good gap-fill characteristics.

Then, the lower insulation layer may be partially removed by a planarization process until a top surface of the signal lines 200 may be exposed and thus the lower insulation layer may remain merely in the first space of the trenches 110 and second spaces between the data wires 210 to 260. Thus, the lower insulation layer may be separated according to the data wires 210 to 260 (node separation), to thereby form the insulation pattern 120 on the substrate 100. The planarization process for the node separation of the lower insulation layer may include a chemical mechanical polishing (CMP) process.

Referring to FIG. 8D, the data wires 210 to 260 may be partially removed from the substrate 100 in the second direction II, and thus a plurality of the recesses may be formed at portions of the data wires 210 to 260.

In an example embodiment, a hard mask layer (not shown) may be formed on the substrate 100 on which the signal lines 200 and the insulation pattern 120 may be formed. Then, the hard mask layer may be formed into a second hard mask pattern 202 by a photolithography process. A surface of the signal lines 200 may be partially exposed through the second hard mask pattern 202. The second hard mask pattern 202 may include a plurality of openings that may be arranged into a regular pattern along the first direction I and the second direction II substantially perpendicular to the first direction I. Thus, the top surface of the signal lines 200 may be exposed through the openings of the second hard mask pattern like a pattern.

For example, a pair of the openings may be arranged along the first direction I and thus two portions of the top surface of the respective data wires 210 to 260 may be exposed along the first direction I on condition that the openings along the second direction II may partially expose the top surfaces of the data wires 210 to 260 that are different from one another. In the present example embodiment, three different openings 202a, 202b and 202c may be arranged in the second hard mask pattern 202 along the second direction II. The arrangement of the opening in the second hard mask pattern 202 may be varied in accordance with the number of the data wires of the signal lines 200 and the number of the coding wirings of the address line 300, as would be known to one of the ordinary skill in the art.

Thereafter, the data wires 210 to 260 of the signal lines 200 may be partially removed form the substrate 100 by an etching process using the second hard mask pattern 202 as an etching mask and thus the top surface of the substrate 100 may be partially exposed through the openings of the second hard mask pattern 202, to thereby form the recesses arranged along the first direction I and the second direction II. In the present example embodiment, six data wires and four coding wirings may be prepared as the signal lines 200 and the address line 300, respectively, according to a half line coding method. Thus, a pair of the recesses may be arranged along the respective data wires 210 to 260 and three recesses may be arranged along the second direction II substantially perpendicular to the data wires 210 to 260.

FIG. 8D exemplarily illustrates a cross-sectional view of the multiplexer 900 shown in FIG. 1 taken along the fourth coding line 340 of the address line 300 and thus the sixth recess 232b, the tenth recess 252b and the twelfth recess 262b are exemplarily illustrated in FIG. 8D. An overall arrangement of the recesses after completing the present process step with reference to FIG. 8D may be the same as shown in FIG. 3

Referring to FIG. 8E, an insulation layer 500 may be formed on the substrate 100 including signal lines 200 having the recesses in accordance with a surface profile of the recesses.

In an example embodiment, the insulation layer 500 may include the insulation interlayer 510 and the gate insulation layer 520. The insulation interlayer 510 may be formed on the data wires 210 to 260 and on the insulation pattern 120 and thus the data wires 210 to 260 may be electrically insulated from the coding lines 310 to 340 of the address line 300 that are formed in the following process described in detail hereinafter. The gate insulation layer 520 may be formed on a bottom of sidewalls of the recesses. That is, the gate insulation layer 520 may be formed on the top surface of the substrate 100 exposed through the recesses and side surfaces of the data wires defining the recesses, and thus the channel region may be formed at the surface potions of the bottom or beneath the bottom of the recesses. The insulation interlayer 510 and the gate insulation layer 520 may be formed in a respective process individually or in an in-situ process simultaneously. In the present example embodiment, the insulation interlayer 510 and the gate insulation layer 520 may be formed in an in-situ process simultaneously.

For example, the insulation layer 500 may comprise silicon oxide (SiOx) or a metal oxide having a high dielectric constant. In the present example embodiment, the insulation layer 500 may comprise a metal oxide having a high dielectric constant to thereby sufficiently reduce a leakage current between the semiconductor structure 410 in the recesses and the channel region of the substrate 100 to minimize an equivalent oxide thickness (EOT) in the recesses. Examples of the metal oxide may include hafnium oxide, titanium oxide, zirconium oxide, aluminum oxide, tantalum oxide and combinations thereof. For example, the insulation layer 500 may be formed on the substrate 100 to have an EOT of about 20 Å to about 400 Å.

Various deposition processes may be utilized for the formation of the insulation layer 500 in accordance with layer characteristics and the EOT. For example, when the insulation layer 500 comprising the metal oxide needs a relatively small thickness, an atomic layer deposition (ALD) process or a cyclic CVD process may be utilized for the formation of the insulation layer 500. In contrast, when the insulation layer 500 comprising the metal oxide needs a relatively large thickness, a PECVD may be utilized in view of process efficiency.

Referring to FIG. 8F, the semiconductor structure 410 may be formed in the recesses of which the bottom and sidewalls may be covered with the gate insulation layer 520 and thus the recesses may be filled up with the semiconductor structure 410.

In an example embodiment, semiconductor materials may be deposited onto the insulation layer 500 to a sufficient thickness to fill up the recesses to thereby form a semiconductor layer (not shown) on the insulation layer 500. Then, the semiconductor layer may be partially removed from the insulation layer 500 by a planarization process until a top surface of the insulation interlayer 510 may be exposed. Therefore, the semiconductor layer may remain in the recesses of which the bottom and the sidewalls may be covered with the gate insulation layer 520, to thereby form the semiconductor structures 410 in the recesses as the switching elements 400. In FIG. 8F, the fourth semiconductor structures 414 making contact with the fourth coding wiring 340 of the address line 300 may be exemplarily illustrated in the sixth recess 232b, the tenth recess 252b and the twelfth recess 262b.

Examples of the semiconductor materials may include silicon (Si), germanium (Ge), gallium (Ga), arsenic (As), polysilicon doped with impurities and combinations thereof. The planarization process for partially removing the semiconductor layer may include a CMP process. In the present example embodiment, the semiconductor structure 410 in the recesses may function as a gate electrode in the recesses and selectively control the flow of the electrons or holes through the channel region beneath the bottom of the recesses.

Therefore, a pair of the gate structures may be arranged in each of the data wires along the first direction I in such a way that three gate structures may make contact with each of the coding lines of the address line 300 along the second direction II. Thus, the gate structures in each of the recesses may be arranged in a line on the substrate 100 along the second direction II. In FIG. 8F, the tenth, the eleventh and the twelfth semiconductor structures 414a, 414b and 414c making contact with the fourth address line 340 of the address line 300 may be exemplarily illustrated. Particularly, the gate structure may include a metal silicide structure having a polysilicon layer and a metal layer on the polysilicon layer to thereby minimize electrical resistance thereof.

Accordingly, the data wiring pieces arranging in the first direction I and symmetric with respect to each of the recesses of which the sidewalls may be covered with the gate insulation layer 520 may function as a source electrode and a drain electrode, respectively, and the semiconductor structure 410 in each of the recesses may function as a gate electrode, and thus a field effect transistor (FET) may be positioned in the recesses of the signal lines 200. The data signal applied to each of the data wires 210 to 260 may be individually connected or short-circuited at each of the recesses by each FET in accordance with the coding signal applied to the coding wirings 310 to 340 of the address line 300. That is, the FET in each recess may function as a switching element for electrically connecting or disconnecting the data wires according to the coding signals. Thus, all of the recesses may be allocated to an electrical on-state or off-state by binary code combinations of the coding wirings 310 to 340 of the address line 300.

Referring to FIG. 8G, the address line 300 may be formed on the semiconductor structures 410 and the insulation interlayer 510 along the second direction II. The address line 300 may make electrical contact with the semiconductor structures 410 in each of the recesses. In FIG. 8G, the fourth semiconductor structure line 414 extending along the fourth coding wiring 340 may be exemplarily illustrated as the representative of the semiconductor structure 410.

In an example embodiment, a second conductive layer (not shown) may be formed on the insulation interlayer 510 and the semiconductor structures 410 in each of the recesses. The second conductive layer may comprise polysilicon, conductive polymer and a metal having a low electrical resistance. Examples of the metal having a low electrical resistance may include copper (Cu), aluminum (Al), platinum (Pt) and tungsten (W). These may be used alone or in combinations thereof. The second conductive line may be formed into the address line 300 in the following process described in detail below. In the present example embodiment, the second conductive layer may comprise the same material as the first conductive layer.

Various deposition processes may be utilized for the formation of the second conductive layer like the first conductive layer. The second conductive layer may be formed in the same process as the first conductive layer, and thus any further detailed descriptions on the deposition processes for the formation of the second conductive layer will be omitted.

The second conductive layer may be patterned by an etching process using an etching mask such as a photoresist pattern into the address line 300 having a plurality of the coding wirings 310 to 340 that may extend in the second direction II. Any other patterning process known to one of the ordinary skill in the art may also be utilized in place of or in conjunction with the etching process in accordance with composition materials of the second conductive layer. For example, the second conductive layer may be patterned into the address line 300 by an imprinting process using a mold pattern corresponding to the address line 300. Particularly, a nano-imprinting process or a nano-lithography process may be utilized for the formation of address line 300 when the second gap distance d2 between the coding wirings of the address line 300 may be significantly reduced. In an example embodiment, each of the coding wirings 310 to 340 may have the second width w2 and may be spaced apart from one another by the second gap distance d2.

Accordingly, a plurality of the coding wirings 310 to 340 may be arranged on the substrate 100 and extend in the second direction II in such a manner that the semiconductor structures may make contact with the coding wirings 310 to 340, respectively, in the second direction II and the coding wirings 310 to 340 may be spaced apart from each other by a predetermined gap distance in the first direction I. The gate insulation layer at a bottom and sidewalls of the recess, the semiconductor structure on the gate insulation layer in the recess, the data wiring pieces symmetric with respect to the recess in the first direction I may be formed into a field effect transistor (FET) in the recess. The FET may function as a switching element for switching on/off the data signal passing through the data wiring of the signal line. The FET may be electrically operated by the binary codes that are combinations of the electrical on/off state of the coding wirings, and thus the switching element may be operated by the binary codes of the coding wirings 310 to 340 of the address line 300.

According to the present example embodiment of manufacturing the multiplexer, a switching element may be formed in the recess of the data wires in a single process and thus a short segment and a conductive segment may be simultaneously formed in the data wiring, to thereby increase process efficiency in manufacturing the multiplexer.

According to the example embodiments of the present inventive concept, the short segment and the conductive segment of a data wiring, which may have different electrical resistance, may be replaced with a single switching element by a single manufacturing process, to thereby increase process efficiency in manufacturing the multiplexer and operation reliability of the multiplexer. Particularly, the multiplexer of the present example embodiment may sufficiently increase electrical connection reliability at a cell region of a memory device in which a plurality of nano-scaled array structures may be arranged and at a peripheral region in which control circuits for controlling the array structures may be arranged. Further, the multiplexer of the present example embodiment may be electrically connected to a data driving unit of a flat panel display (FPD) device in which various image data signals may be transferred to the pixels of a display unit of the FPD, to thereby improve data transfer efficiency in the FPD.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A multiplexer comprising:
a signal line arranged on a substrate and comprising a plurality of data wires extending in a first direction electrically insulated from one another, each of the data wires having at least one recess to provide at least two data wiring pieces;
an address line arranged on the signal line and including a plurality of coding lines extending in a second direction different from the first direction and electrically insulated from the data wires; and
a plurality of switching elements positioned in the recesses of the data wires and making electrical contact with the coding lines, the switching element configured to switch a data signal applied to the data wiring on and off in accordance with a coding signal applied to the coding lines, so that one of the data wires is selected according to a binary code of the address line corresponding to combinations of the coding lines to which coding signal is applied.

2. The multiplexer of claim 1, further comprising an insulation pattern between the data wires adjacent to each other to electrically insulate the data wiring and an insulation interlayer on the insulation pattern and on the data wiring, so that the address line is arranged on the insulation interlayer in the second direction and electrically insulated from the data wires underlying the insulation interlayer.

3. The multiplexer of claim 2, wherein the substrate includes a trench between the data wires adjacent to each other, the trench having a bottom lower than a surface of the substrate and being filled with the insulation pattern.

4. The multiplexer of claim 2, wherein a pair of the recesses are positioned at each of the data wires extending in the first direction such that a pattern of the recesses at each of data wires is different from each other in the first direction and at least two recesses positioned in different data wires are arranged in a line along the second direction, so that the switching elements in the recesses are arranged in a line along the coding wirings extending in the second direction.

5. The multiplexer of claim 4, further comprising a gate insulation layer covering a surface of the substrate exposed through the recess and sidewalls of the data wiring pieces that define the recess, so that the switching element includes a field effect transistor (FET) having a gate structure that is positioned on the gate insulation layer in the recess.

6. The multiplexer device of claim 5, wherein the gate insulation layer and the insulation interlayer include one of silicon oxide and metal oxide having high dielectric constant.

7. The multiplexer of claim 5, wherein the signal line and the address line includes any one material selected from the group consisting of polysilicon doped with impurities, a metal and a conductive polymer.

8. A method of forming a multiplexer, comprising:
forming a signal line on a substrate, the signal line including a plurality of data wires extending in a first direction and electrically insulated from one another, each of the data wires having at least one recess such that the data wires are separated into at least two data wiring pieces;
forming a plurality of switching elements in the recesses of the data wires, the switching element being arranged in a second direction different from the first direction and configured to switch a data signal applied to the data wiring on and off in accordance with a coding signal; and
forming an address line on the signal line, the address line including a plurality of coding lines extending in the second direction and electrically insulated from the data wires such that the coding lines make electrical contact with the switching elements, so that one of the data wires is selected according to a binary code of the address line corresponding to combinations of the coding lines to which the coding signal is applied.

9. The method of claim 8, wherein forming the signal line including the data signals includes:
forming a first conductive layer on the substrate;
forming a hard mask pattern on the first conductive layer, so that the first conductive layer partially exposed through the hard mask pattern;
partially removing the first conductive layer by an etching process using the hard mask pattern as an etching mask, to thereby form a first conductive pattern; and
removing the hard mask pattern from the first conductive pattern.

10. The method of claim 8, wherein forming the switching elements includes:
forming an insulation pattern on the substrate such that a gap space between the data wires is filled with the insulation pattern and the data wires are electrically insulated from one another;
forming a pair of the recesses at each of the data wires extending in the first direction such that a pattern of the recesses at each of data wires is different from each other in the first direction and at least two recesses positioned in different data wires are arranged in a line along the second direction, so that the switching elements in the recesses are arranged in a line along the coding lines extending in the second direction;
forming an insulation layer on the data wires, on the insulation pattern, on a surface of the substrate exposed through the recess and on sidewalls of the data wiring pieces that define the recess; and
forming semiconductor structures on the insulation layer in the recesses of the data wires of the signal line;
